(19) United States
(12) Patent Application Publication
(10) Pub. No.: US 2020/0251572 A1
(43) Pub. Date: Aug. 6, 2020

(54) METHOD FOR MANUFACTURING SELF-ALIGNED SIGE HBT DEVICE BY NONSELECTIVE EPITAXY

(71) Applicant: Shanghai Huahong Grace Semiconductor Manufacturing Corporation, Shanghai (CN)

(72) Inventor: Zhengliang ZHOU, Shanghai (CN)

(73) Assignee: Shanghai Huahong Grace Semiconductor Manufacturing Corporation, Shanghai (CN)

(21) Appl. No.: 16/727,330

(22) Filed: Dec. 26, 2019

(30) Foreign Application Priority Data
Jan. 31, 2019 (CN) 201910098259.7

(51) Int. Cl. H01L 29/66; H01L 21/02; H01L 21/3065; H01L 21/311; H01L 29/04; H01L 29/165; H01L 29/167; H01L 29/737

(52) U.S. Cl. CPC H01L 29/66242; H01L 21/02532; H01L 21/02595; H01L 21/02576; H01L 21/02661; H01L 29/7375; H01L 21/02164; H01L 21/31116; H01L 29/04; H01L 29/165; H01L 29/167; H01L 21/3065

(57) ABSTRACT

A method for manufacturing a self-aligned SiGe HBT device by nonselective epitaxy. An expected germanium concentration, an expected boron doping percent and an expected carbon concentration can be obtained within a wide range by low-temperature selective epitaxy of SiGe. However, due to the influences of different doping ratios on the selectivity of epitaxial growth, a desired impurity distribution can be obtained after repeated experiments when selective epitaxy is used for device research and development, thus, delaying the research and development progress. According to the method of the present disclosure, nonselective epitaxy is adopted in an extrinsic base region, so that a deposition layer can be monocrystalline or polycrystalline, process complexity is low, and device performance is good.

### CROSS REFERENCE TO RELATED APPLICATION

This application claims the priority of Chinese patent application number 201910098259.7, filed on Jan. 31, 2019, the entire contents of which are incorporated herein by reference.

### FIELD OF THE INVENTION

The present disclosure relates to the field of semiconductor integrated circuits, in particular to a method for manufacturing a self-aligned SiGe HBT device by nonselective epitaxy.

### BACKGROUND

Self-aligned devices using P-type polysilicon to elevate the extrinsic base region and having an inner spacer between the emitter and the extrinsic base region can decrease the base resistance as well as the base-collector capacitance. SiGe heterojunction bipolar transistor (HBT) devices of such structure have the maximum oscillation frequency fmax over 300 GHz and are equivalent to III-V devices in performance, thereby being widely applied to photo-communications and millimeter waves.

The base of the SiGe HBT devices is made from a SiGe carbon alloy having a small energy bandwidth and doped with boron impurities. Because there is an energy band difference between the emitter and the base, heavy base doping can be adopted without changing the direct-current amplification factor HFE, so as to obtain high fmax.

The base resistance includes the resistance of an extrinsic base region and the resistance of an intrinsic base region (the resistance under the emitter) and is an important parameter for increasing fmax. In order to decrease the base resistance, the doping concentration of the base region should be increased to the maximum extent, and the width of the emitter window and the spacer should be decreased to the maximum extent.

The cut-off frequency fT and the maximum oscillation frequency of the SiGe HBT devices are represented by the following formulas:

$$\frac{1}{2 π {f}_{T}} = {τ}_{E} + \frac{{W}_{B}^{2}}{2 {D}_{nB}} + \frac{{W}_{BC}}{2 {v}_{sat}} + \frac{kT}{{qI}_{c}} ( {C}_{BE} + {C}_{BC} ) + {C}_{BC} ( {R}_{E} + {R}_{C} )$$

$${f}_{max} = \sqrt{\frac{{f}_{T}}{S π {R}_{E} {C}_{BC}}}$$

In the prior art, self-aligned SiGe HBT devices are formed by selective epitaxy through the process shown in FIGS. 1-3: after a collector is formed, a SiO2 (silicon dioxide)/poly (heavily boron-doped polysilicon)/SiO2/SiN (silicon nitride)/SiO2 laminated layer is deposited, then an emitter window is opened to carry out dry etching, and dry etching is stopped on bottom SiO2, as shown in FIG. 1.

After wet-etching and cleaning, SiGe is grown (only in the source region and the polysilicon region) by selective epitaxy, and then a dielectric is deposited and is etched-back to form an inner spacer, as shown in FIG. 2.

After wet etching and cleaning, heavily As-doped polysilicon is deposited, and then emitter polysilicon and base polysilicon are etched to form an emitter and a base, as shown in FIG. 3.

The integration scheme of this method is simple. However, due to the fact that selective SiGe epitaxy is needed, it will be challengeable to obtain non-defective SiGe epitaxial layers with the gradual decrease of the lateral dimension of devices.

### SUMMARY

The technical issue to be settled by this application is to provide a method for manufacturing a self-aligned SiGe HBT device by nonselective epitaxy, so that a non-defective SiGe epitaxial layer can still be obtained when the lateral dimension of the device is greatly decreased.

To settle the above technical issue, the present disclosure discloses a method for manufacturing a self-aligned SiGe HBT device by nonselective epitaxy. The method comprises the following steps:

Step 1, carrying out lithography and etching to form a SiGe epitaxial window, forming a SiGe layer by low-temperature nonselective epitaxy, and then depositing a silicon oxide-polysilicon-silicon oxide laminated layer;

Step 2, carrying out lithography and dry-etching via a sacrificial emitter window, and stopping photo-etching and dry-etching on the SiGe layer, so that only an extrinsic base region of the window is opened;

Step 3, depositing polysilicon to cover surfaces and side faces of a whole chip, depositing a planarization organic dielectric, and then etching-back the organic dielectric and the polysilicon;

Step 4, depositing silicon oxide, depositing the planarization organic dielectric, and then etching-back the organic dielectric and the silicon oxide;

Step 5, etching the polysilicon to remove the polysilicon outside the extrinsic base region;

Step 6, depositing silicon oxide and etching-back the silicon oxide to form an inner spacer;

Step 7, after wet-etching and cleaning, depositing heavily As-doped polysilicon, and then etching the polysilicon to form an emitter;

Step 8, lithography and dry-etching the base polysilicon, then depositing silicon oxide, and etching-back the silicon oxide to form an emitter polysilicon spacer.

Preferably, a silicon oxide layer, a polysilicon layer and a silicon oxide layer in the silicon oxide-polysilicon-silicon oxide laminated layer deposited in Step 1 respectively have a thickness of 200 Å, a thickness of 2000 Å and a thickness of 500-800 Å.

Preferably, the polysilicon deposited in Step 3 has a thickness of 500 Å.

Preferably, the organic dielectric and the polysilicon are etched-back in Step 3 until the height of the polysilicon is smaller than that of the polysilicon at the sacrificial emitter window by over 1000 Å.

Preferably, the silicon oxide deposited for the first time in Step 4 has a thickness over 500 Å, and the organic dielectric deposited in Step 4 has a thickness of 2000 Å.

Preferably, in Step 4, the organic dielectric and the silicon oxide are etched-back to be removed until the surface of the polysilicon is exposed.

Preferably, in Step 5, dry-etching is carried to remove the polysilicon and stops on silicon oxide.

Preferably, the silicon oxide deposited in Step 6 has a thickness of 500 Å.

Preferably, the heavily As-doped polysilicon deposited in Step 6 has a thickness of 800-1200 Å.

According to the method provided by the present disclosure, low-temperature nonselective epitaxy is used for SiGe growth, polysilicon is deposited after the sacrificial emitter window is formed, a dielectric layer is repeatedly deposited and etched-back to form the elevated polysilicon spacer of the extrinsic base region, and finally, a standard self-aligned device with the emitter polysilicon isolated from the base region polysilicon by the spacer is formed. Compared with the prior art, selectively-grown extrinsic base region polysilicon is replaced with common furnace polysilicon, so that the special selective epitaxy process is omitted for chip manufacturers, and the method is more beneficial to mass production.

### BRIEF DESCRIPTION OF THE DRAWINGS

FIGS. 1-3 are schematic diagrams of main steps of prior art for forming a self-aligned HBT by selective SiGe epitaxy.

FIG. 4 is a schematic diagram of a silicon oxide-polysilicon-silicon oxide layer deposited through the method of the present disclosure.

FIG. 5 is a schematic view of a device formed after a sacrificial emitter window is lithography and dry-etched through the method of the present disclosure.

FIGS. 6-7 are schematic diagrams of the device formed after polysilicon and a planarization organic dielectric are deposited and then etched-back through the method of the present disclosure.

FIGS. 8-10 are schematic diagrams of the device formed after silicon oxide and the planarization organic dielectric are deposited and the planarization organic dielectric, the silicon oxide and the polysilicon are etched-back through the method of the present disclosure.

FIG. 11 is a schematic diagram of the device formed after silicon oxide is deposited and is etched-back to form an inner spacer through the method of the present disclosure.

FIG. 12 is a schematic diagram of the device formed after heavily As-doped polysilicon is deposited and is then etched to form an emitter through the method of the present disclosure.

FIG. 13 is a schematic device of a HBT device finally obtained through the method of the present disclosure.

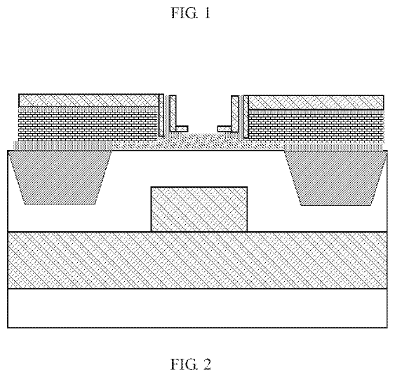

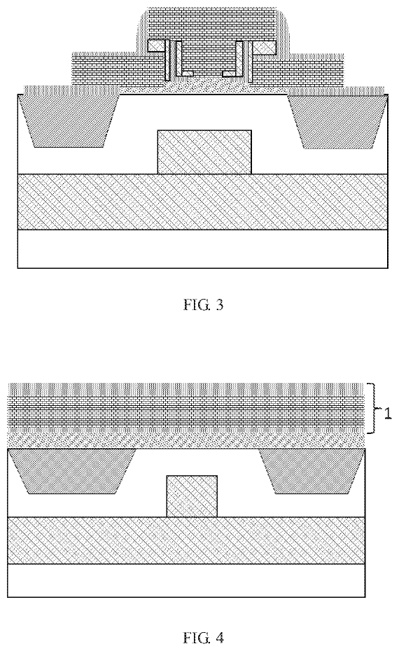

Reference Signs: 1, silicon oxide-polysilicon-silicon oxide laminated layer; 2, polysilicon; 3, planarization organic dielectric; 4, silicon oxide; 5, inner spacer.

### DETAILED DESCRIPTION

Specific embodiments of the present disclosure are disclosed below. It should be understood that these embodiments are only illustrative ones of the present disclosure and can be implemented in various forms. Thus, specific structural and functional details disclosed below should not be regarded as restrictive to the present disclosure. Furthermore, nouns and terms in this application are used to provide a comprehensible description of the present disclosure and are not restrictive either. The present disclosure can be better understood with reference to the following description and the accompanying drawings. In this application, identical reference signs refer to identical elements, and the accompanying drawings are drawn not to scale.

In one preferred embodiment, the method for manufacturing a self-aligned SiGe HBT device by nonselective epitaxy comprises the following steps:

Step 1, as shown in FIG. 4, a SiGe epitaxial window is formed by lithography and etching, a SiGe layer is formed by low-temperature nonselective epitaxy, and then a silicon oxide-polysilicon-silicon oxide laminated layer is deposited. In this embodiment, a silicon oxide layer, a polysilicon layer and a silicon oxide layer in the silicon oxide-polysilicon-silicon oxide laminated layer 1 respectively have a thickness of 200 Å, a thickness of 2000 Å and a thickness of 500-800 Å.

Step 2, as shown in FIG. 5, lithography and dry-etching are carried out via a sacrificial emitter window and are stopped on the SiGe layer, so that only an extrinsic base region of the window is opened.

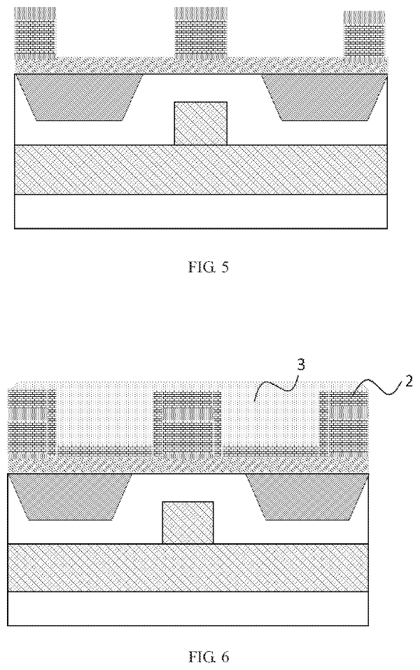

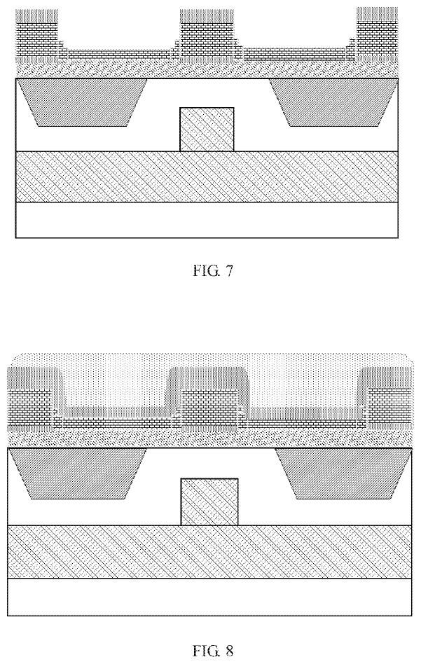

Step 3, as shown in FIGS. 6-7, polysilicon 2 is deposited and covers surfaces and side faces of a whole chip, a planarization organic dielectric 3 is deposited, and then the organic dielectric and the polysilicon are etched back. In this embodiment, the thickness of the deposited polysilicon 2 is 500 Å, and the organic dielectric 3 and the polysilicon 2 are etched back until the height of the polysilicon 2 is smaller than that of the polysilicon at the sacrificial emitter window by over 1000 Å.

Step 4, silicon oxide 4 is deposited, the planarization organic dielectric 3 is deposited, and then the organic dielectric 3, the silicon oxide 4 and the polysilicon are etched-back, as shown in FIGS. 8-10.

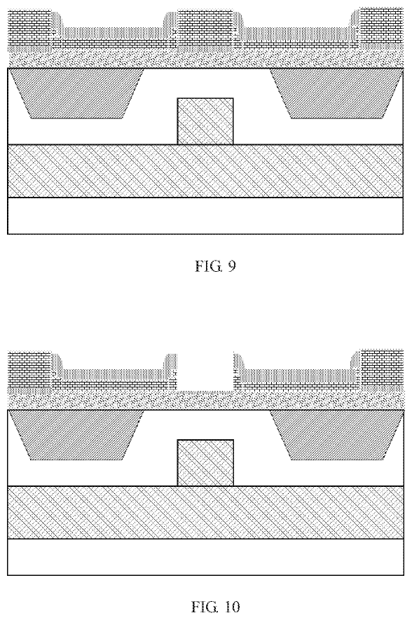

As shown in FIGS. 8-9, one layer of silicon oxide having a thickness of 500-1000 Å is deposited first to isolate an emitter and a base of the device; then, a layer of planarization organic dielectric having a thickness of about 2000 Å is deposited; and afterwards, the organic dielectric and the silicon oxide are etched-back until the silicon oxide at the top of the polysilicon is etched away, wherein the organic dielectric should be dry-etched, and the silicon oxide can be dry-etched, wet-etched or both dry-etched and wet-dried.

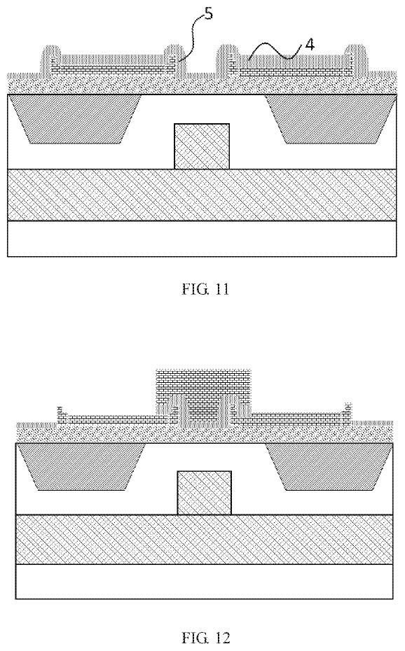

Step 5, as shown in FIG. 10, dry-etching is carried out to remove the polysilicon and is stopped on the silicon oxide at the bottom of the laminated layer.

Step 6, as shown in FIG. 11, silicon oxide 4 is deposited and is etched-back to form an inner spacer 5. In this embodiment, the thickness of the deposited silicon oxide is 500 Å.

Step 7, after wet etching and cleaning, heavily As-doped polysilicon is deposited and is then etched to form an emitter, as shown in FIG. 12. In this embodiment, the thickness of the deposited heavily As-doped polysilicon is 800-1200 Å.

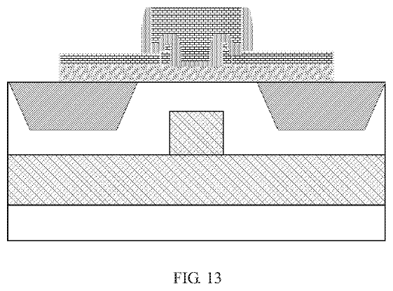

Step 8, the base polysilicon is lithography and dry-etched, and then silicon oxide is deposited and etched-back to form an emitter polysilicon spacer, as show in FIG. 13.

The method of the present disclosure can be easily integrated with exiting CMOS processes, and all processes involved in the method, such as low-temperature nonselective epitaxy of SiGe and deposition and etching-back of organic dielectrics, are mature processes for semiconductor manufacturers, and a technological process suitable for mass production is easily achievable. An expected germanium concentration, an expected boron doping percent and an expected carbon concentration can be obtained within a wide range by low-temperature selective epitaxy of SiGe; however, due to the influences of different doping ratios on the selectivity of epitaxial growth, a desired impurity distribution can be obtained after repeated experiments when selective epitaxy is used for device research and development, thus, delaying the research and development progress. According to the method of the present disclosure, nonselective epitaxy is adopted in an extrinsic base region, so that a deposition layer can be monocrystalline or polycrystalline, process complexity is low, and device performance is good.

In addition, what should to be noted is that only otherwise specified or pointed out, terms, such as ‘first’, ‘second’ and ‘third’, involved in the specification are only intended to distinguish components, elements and steps in the specification, but do not indicate logical or sequential relations between the components, elements and steps.

The present disclosure is detailed above with specific implementations and embodiments, but the present disclosure is not limited to these specific implementations and embodiments. Various transformations and improvements can be made by those skilled in this field without deviating from the principle of the present disclosure, and all these transformations and improvements should also fall within the protection scope of the present disclosure.

What is claimed is:

1. A method for manufacturing a self-aligned SiGe HBT device by nonselective epitaxy, wherein the method comprises the following steps:
Step 1, after a collector is formed, carrying out lithography and etching to form a SiGe epitaxial window, forming a SiGe layer by low-temperature nonselective epitaxy, and then depositing a silicon oxide-polysilicon-silicon oxide laminated layer;
Step 2, carrying out lithography and dry-etching via a sacrificial emitter window, and stopping on the SiGe layer, so that only an extrinsic base region of the window is opened;
Step 3, depositing polysilicon to cover surfaces and side faces of a whole chip, depositing a planarization organic dielectric, and then etching-back the organic dielectric and the polysilicon;
Step 4, depositing silicon oxide, depositing the planarization organic dielectric, and then etching-back the organic dielectric and the silicon oxide;
Step 5, etching the polysilicon to remove the polysilicon outside the extrinsic base region;
Step 6, depositing silicon oxide and etching-back the silicon oxide to form an inner spacer;
Step 7, after wet-etching and cleaning, depositing heavily As-doped polysilicon, and then etching the polysilicon to form an emitter; and
Step 8, lithography and dry-etching the base polysilicon, then depositing silicon oxide, and etching-back the silicon oxide to form an emitter polysilicon spacer.

2. The method for manufacturing a self-aligned SiGe HBT device by nonselective epitaxy according to claim 1, wherein a silicon oxide layer, a polysilicon layer and a silicon oxide layer in the silicon oxide-polysilicon-silicon oxide laminated layer deposited in Step 1 respectively have a thickness of 200 Å, a thickness of 2000 Å and a thickness of 500-800 Å.

3. The method for manufacturing a self-aligned SiGe HBT device by nonselective epitaxy according to claim 1, wherein the polysilicon deposited in Step 3 has a thickness of 500 Å.

4. The method for manufacturing a self-aligned SiGe HBT device by nonselective epitaxy according to claim 1, wherein the organic dielectric and the polysilicon are etched-back in Step 3 until a height of the polysilicon is smaller than that of the polysilicon at the sacrificial emitter window by over 1000 Å.

5. The method for manufacturing a self-aligned SiGe HBT device by nonselective epitaxy according to claim 1, wherein the silicon oxide deposited in Step 4 has a thickness over 500 Å, and the organic dielectric deposited in Step 4 has a thickness of 2000 Å.

6. The method for manufacturing a self-aligned SiGe HBT device by nonselective epitaxy according to claim 1, wherein in Step 4, the organic dielectric and the silicon oxide are etched-back to be removed until a surface of the polysilicon is exposed.

7. The method for manufacturing a self-aligned SiGe HBT device by nonselective epitaxy according to claim 1, wherein in Step 5, dry-etching is carried to remove the polysilicon outside the extrinsic base region and is stopped on the silicon oxide.

8. The method for manufacturing a self-aligned SiGe HBT device by nonselective epitaxy according to claim 1, wherein the silicon oxide deposited in Step 6 has a thickness of is 500 Å.

9. The method for manufacturing a self-aligned SiGe HBT device by nonselective epitaxy according to claim 1, wherein the heavily As-doped polysilicon deposited in Step 7 has a thickness of 800-1200 Å.
